(19) United States
(12) Patent Application Publication
(10) Pub. No.: US 2016/0345435 A1
(43) Pub. Date: Nov. 24, 2016

(54) PRINT CIRCUIT BOARD

(71) Applicant: SHENZHEN CHINA STAR OPTOELECTRONICS TECHNOLOGY CO. LTD., Guangdong (CN)

(72) Inventors: Jianyong FU, Shenzhen, Guangdong (CN); Wendong LI, Shenzhen, Guangdong (CN)

(73) Assignee: Shenzhen China Star Optoelectronics Technology Co. Ltd., Shenzhen, Guangdong (CN)

(21) Appl. No.: 14/426,747

(22) PCT Filed: Nov. 28, 2014
(86) PCT No.: PCT/CN2014/092581

§ 371 Date: Mar. 7, 2015

(30) Foreign Application Priority Data
Nov. 13, 2014 (CN) 201410643189.6

(51) Int. Cl. H05K 1/11

(52) U.S. Cl. CPC H05K 1/111; H05K 2201/094

(57) ABSTRACT

A print circuit board is disclosed, which comprises: a board body; and two pad sets being disposed relatively on the board body along a first direction, wherein each of the pad set comprises a first pad and a second pad being disposed relatively along a second direction being vertical to the first direction, wherein specifications of the first pad and the second pad are different. The print circuit board can suit for the electronic components with the different sizes, and the area of the print circuit board can be reduced, and the utilization of the print board circuit material is enhanced. At the same time, the situation can be avoided which is that the excessive paste will be used to move the component when playing piece and then result in many mounting issues.

### FIELD OF THE INVENTION

The present invention relates to a print circuit board; in particular, to a print circuit board with the electronic components having different sizes.

### BACKGROUND OF THE INVENTION

For the design of the print circuit board, the package formation of the electronic components (such as inductors and resistors) is set up based on the datasheet provided by the suppliers currently. In the datasheet, the specific sizes (such as pin size) of the electronic components and pad sizes are provided, and a electronic component is relative to a package. When the sizes of two electronic components are not different in the datasheet, they can be designed together into one package. If two electronic components are designed into one package when the pin sizes of them are much different, the excessive paste will be used to move the component when playing piece. That will result in the mounting issues.

### SUMMARY OF THE INVENTION

In order to solve the problem existing in the conventional art, the aim of the present invention is to provide a print circuit board comprising a board body and two pad sets being disposed relatively on the board body along a first direction, wherein each of the pad sets comprises a first pad and a second pad being disposed relatively along a second direction being vertical to the first direction, wherein specifications of the first pad and the second pad are different.

Further, the first pad and the second pad are rectangular shape.

Further, length of the first pad is shorter than length of the second pad, and width of the first pad is equal to width of the second pad.

The other aim of the present invention is to provide a print circuit board, comprising a board body; and two pad sets being disposed relatively on the board body along a first direction, wherein each of the pad sets comprises a first pad and a second pad being disposed relatively along a second direction being vertical to the first direction, the first pad and the second pad are rectangular shape, length of the first pad is shorter than length of the second pad, and width of the first pad is equal to width of the second pad.

The print circuit board of the present invention is available to suit for welding the electronic components with different sizes, and the area of the print circuit board can be reduced, and the utilization of the print board circuit material is enhanced. At the same time, the situation can be avoided which is that the excessive paste will be used to move the component when playing piece and then result in many mounting issues.

### BRIEF DESCRIPTION OF THE DRAWINGS

The following description of the drawings The above and other exemplary aspects, features and advantages of certain exemplary embodiments of the invention will become more apparent, wherein:

FIG. 1 is the schematic diagram of the print circuit board of the embodiment of the present invention.

### DETAILED DESCRIPTION OF THE PREFERRED EMBODIMENTS

Hereinafter, embodiments of the present invention will be described in detail with reference to the accompanying drawings. However, be in many different forms and embodiments of the present invention, and the present invention should not be construed as limited to the specific embodiments set forth herein. Rather, these embodiments are provided to explain the principles of the invention and its practical application so that others skilled in the art to understand the invention for various embodiments and various modifications suited to the particular intended application.

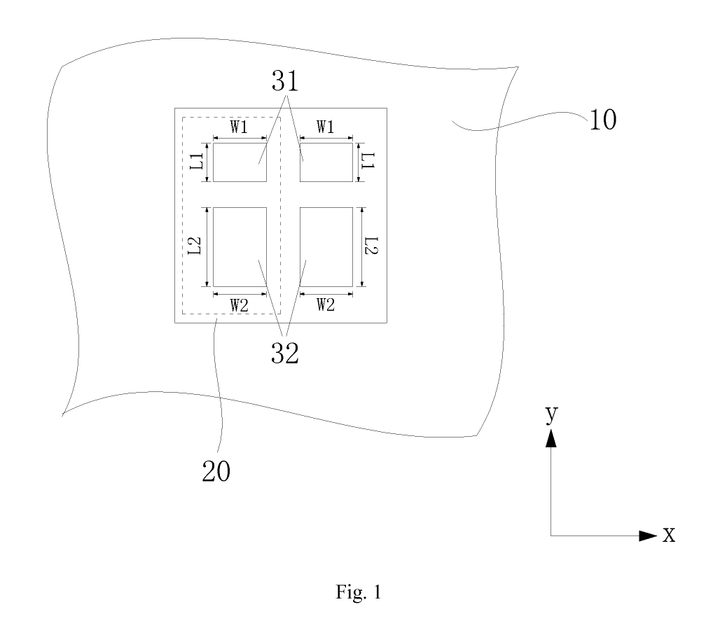

FIG. 1 is a schematic diagram of a print circuit board according to the present embodiment.

Refer to FIG. 1. A print circuit board comprises a board body 10 and two pad sets where at least one welding area 20 on the surface of the board body 10 and the two pad sets are disposed relatively in the welding area 20 along the first direction. Each of the pad sets comprises a first pad 31 and a second pad 32 along the second direction which is vertical to the first direction. Also, the sizes of the first pad 31 and the second pad 32 are different.

In the present embodiment, the first direction can be x direction; and the second direction can be y direction vertical to x direction, but the present invention cannot be limited herein. As a preferred embodiment, the first direction can be arbitrary direction on the surface of the board body 10 and the second direction can be on the surface of the board body 10 and vertical to the first direction.

The present invention is not limited by the amount of the pad of each of the pad sets shown in FIG. 1. The amount of the pad can be based on the size of the electronic components. For example, each of the pad sets comprises three pads disposed relatively to each other along the second direction.

In the present embodiment, the first pad 31 and the second pad 32 are rectangular shape. The different specification of the first pad 31 and the second pad 32 is that the length L1 of the first pad 31 is not smaller than the length L2 of the second pad 32 and the width W1 of the first pad 31 is equal to the width W2 of the second pad 32.

In summary, the welding area 20 is used for welding the electronic components with different sizes For example, when the pin length of the electronic components is equal to the length L1 of the first pad 31, the pins at two sides of the electronic components are welded respectively with the two first pads 31 which are closed to each other; when the pin length of the electronic components is equal to the length L1 of the first pad 31 and the length L2 of the second pad 32, the pin at the one side of the electronic components are welded respectively with the one pad set (i.e. one of the two first pads 31 and the second pad 32 at the same side as the first pad 31). Moreover, based on the print circuit board design of the embodiment, the present invention avoids that the different welding areas are designed for welding the same type electronic components with different size on the same print circuit board. The area of the print circuit board is reduced and the utilization of the print board circuit material is enhanced. At the same time, the situation can be avoided which is that the excessive paste will be used to move the component when playing piece and then result in many mounting issues.

Although reference to certain exemplary embodiments of the present invention is shown and described the present invention, those skilled in the art should understand that in the case without departing from the spirit and scope of the appended claims and their equivalents of the invention as defined next, in the form and details of the present invention, various changes.

What is claimed is:

1. A print circuit board, comprising:
a board body; and
two pad sets being disposed relatively on the board body along a first direction, wherein each of the pad set comprises a first pad and a second pad being disposed relatively along a second direction being vertical to the first direction, wherein specifications of the first pad and the second pad are different.

2. The print circuit board as claimed in claim 1, wherein the first pad and the second pad are rectangular shape.

3. The print circuit board as claimed in claim 2, wherein length of the first pad is shorter than length of the second pad, and width of the first pad is equal to width of the second pad.

4. A print circuit board comprises:
a board body; and
two pad sets being disposed relatively on the board body along a first direction, wherein each of the pad sets comprises a first pad and a second pad being disposed relatively along a second direction being vertical to the first direction, the first pad and the second pad are rectangular shape, length of the first pad is shorter than length of the second pad, and width of the first pad is equal to width of the second pad.
